(19) United States
(12) Patent Application Publication
(10) Pub. No.: US 2008/0169947 A1
(43) Pub. Date: Jul. 17, 2008

(54) Analog-to-Digital Converter with DC Balanced Serialized Output

(76) Inventor: Marcellus C. Harper, Kaysville, UT (US)

Correspondence Address: STEVEN L. NICHOLS;RADER, FISHMAN & GRAVER PLLC, 10653 S. RIVER FRONT PARKWAY, SUITE 150, SOUTH JORDAN, UT, 84095, US

(21) Appl. No.: 12/013,039

(22) Filed: Jan. 11, 2008

Related U.S. Application Data
(60) Provisional application No. 60/880,111, filed on Jan. 11, 2007.

(51) Int. Cl. H03M 9/00

(52) U.S. Cl. 341/101

(57) ABSTRACT

A method of serializing parallel output from an analog-to-digital converter includes receiving a parallel output from an analog-to-digital converter; serializing the parallel output; and encoding the serialized output such that it is DC balanced. A system for serializing and DC balancing an analog-to-digital converter output includes an analog-to-digital converter that outputs digital data over a parallel bus; a serializer configured to receive said digital data from said parallel bus, said serializer serializing said digital data into serial output; and a means for encoding the serial output such that it is DC balanced.

### RELATED APPLICATIONS

This application claims the benefit under 35 U.S.C. §119(e) of U.S. Provisional Patent Application No. 60/880,111 filed Jan. 11, 2007 entitled “Test Solutions and Methods for Difficult Case Signals Encountered in Automatic Test Equipment.” The afore mentioned application is incorporated herein by reference in its entirety.

### BACKGROUND

High speed analog-to-digital converters are required to digitize analog signals. According to one exemplary embodiment, the analog-to-digital converters output the digitized data through a parallel output port with one bit being output per line. The parallel output port has the advantage of high data throughput. However, using a parallel output bus to transmit data from an analog-to-digital converter has several disadvantages including a large numbers of traces, larger package size, noise susceptibility, timing skew between signals and high power consumption.

### BRIEF DESCRIPTION OF THE DRAWINGS

The accompanying drawings illustrate various embodiments of the principles described herein and are a part of the specification. The illustrated embodiments are merely examples and do not limit the scope of the disclosure.

FIG. 1 illustrates an exemplary analog-to-digital converter (ADC) that has a DC-balanced serialized output stream, according to principles described herein.

FIG. 2 illustrates an exemplary data serialization scheme for the ADC in FIG. 1, according to the principles described herein.

Throughout the drawings, identical reference numbers designate similar, but not necessarily identical, elements.

### DETAILED DESCRIPTION

In the following description, for purposes of explanation, numerous specific details are set forth in order to provide a thorough understanding of the present systems and methods. It will be apparent, however, to one skilled in the art that the present apparatus, systems and methods may be practiced without these specific details. Reference in the specification to “an embodiment,” “an example” or similar language means that a particular feature, structure, or characteristic described in connection with the embodiment or example is included in at least that one embodiment, but not necessarily in other embodiments. The various instances of the phrase “in one embodiment” or similar phrases in various places in the specification are not necessarily all referring to the same embodiment.

In many pieces of automated test equipment, analog-to-digital converters are used to capture a signal and convert it into digital information for manipulation or later analysis. In digital testing applications, it can be desirable to acquire high-frequency characteristics of the digital signals such as skew, slew, overvoltage, undervoltage, rise times, fall times, or other parameters. In these and many other applications high-speed analog-to-digital converters are used. According to one exemplary embodiment, the analog-to-digital converters output the digitized data through a parallel output port with one bit being output per line. The parallel output port has the advantage of rapidly outputting data. Particularly, in CMOS applications a parallel bus may be required because data can't be driven serially at a higher data rate per output signal. However, if the analog-to-digital converter must drive the output digital signals over a substantial distance, a substantial amount of electrical power can be consumed simply to drive the signals. It is important to minimize the power used in transmitting signals because the high-speed analog-to-digital converters can be one of the highest power consuming chips in a system and run at the highest temperature.

Using a parallel output bus to transmit data from an analog-to-digital converter has several disadvantages. First the parallel output is often single ended output, which is susceptible to noise and other physical effects. Additionally, the parallel output port contains a large number of lines which increases the size of the ADC package and each line must be carefully routed on the printed circuit board to avoid undesirable signal delay, jitter, and skew. To minimize the power requirement and the distance over which the parallel output port must operate, a serializer may be used to combine the parallel outputs into a serial stream. The serial data stream can be output from the serializer on differential or single ended serial lines. According to one exemplary embodiment, the serial stream can travel over differential pairs, which can be less susceptible to noise and routing considerations. Additionally, by serializing the output of an analog-to-digital converter, the total number of output lines can be reduced which can lower overall operating power. According to one exemplary embodiment, the serialized signal can operate in Low Voltage Differential Signal (LVDS) mode.

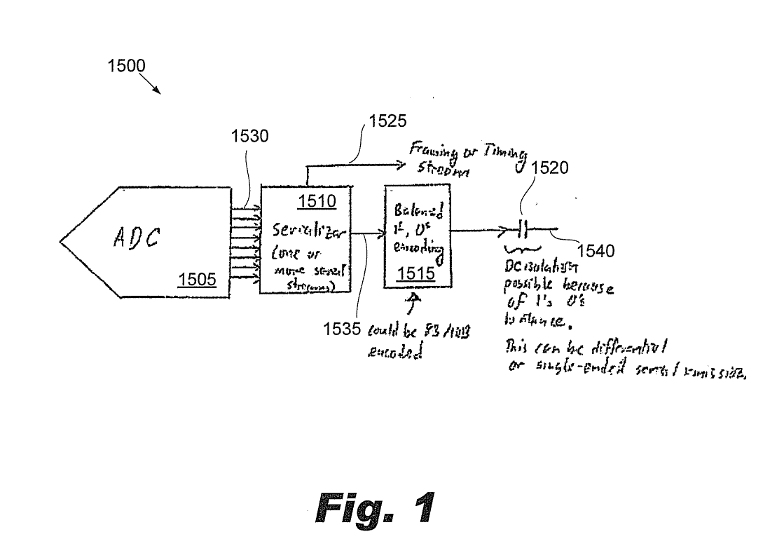

FIG. 1 shows an analog-to-digital converter (ADC) (1500) that features an ADC core (1505) with the parallel output (1530). Although there could be any number of output lines exiting the analog-to-digital converter core (1505), for clarity of description only eight parallel output lines (1530) are shown. A serializer (1510) accepts the parallel outputs (1530) and generates a serial data stream (1535). Only one serial stream is shown, however the actual number of streams from the serializer (1510) can vary. According to one exemplary embodiment, the serializer (1510) also outputs a framing and/or timing stream (1525). This framing or timing stream (1525) allows downstream devices to parse the serialized data stream and understand its contents.

In many instances it can be desirable to separate the output from the analog-to-digital converter core (1505) and serializer (1510) from other circuitry by using an isolation capacitor (1520). The isolation capacitor is only one embodiment of several means of passing an AC signal while blocking any DC component of the signal. The DC isolation capacitor (1520) can be thought of as a pair of plates, with the first upstream plate being electrically connected to the upstream portion of the serialized output line (1535) and an adjacent but physically separate plate being connected to the downstream output line (1540). The DC isolation capacitor (1520) allows high-frequency signals to pass through it without substantial interference. However, lower frequency or DC signals are blocked by the DC isolation capacitor (1520). This protects the analog-to-digital converter core (1505) and serializer (1510) from undesirable outside influences such as eddy currents in ground loops. This improves the overall signal quality received out of the analog-to-digital converter core (1505).

When the DC isolation capacitor (1520) receives a stream of high-frequency digital data comprising a series of high-voltage and low voltage pulses representing digital “1”s and “0”s, the voltage on the upstream plate varies accordingly. The downstream plate of the capacitor senses the changes in voltage on the upstream plate and transmits the voltage pulses into the downstream line (1540). Over time, the average DC voltage of the downstream drifts from the DC offset of the upstream signal. This drift can occur when an unbalanced number of “1”s and “0”s are transmitted from the upstream serializer (1510). For example, if significantly more digital “1”s than “0”s are transmitted by the serializer (1510), the average downstream voltage may gradually diminish until the logic level appears to be a logic level “0”. Serial streams with significantly more “1”s or “0”s are unbalanced and therefore can cause errors in data received downstream line. According to one exemplary embodiment, the serializer (1510) output can be encoded such that the number of digital “1”s or “0”s are transmitted over a given time period is balanced, thereby preventing bit errors or other errors due to the isolation component in the downstream line (1540).

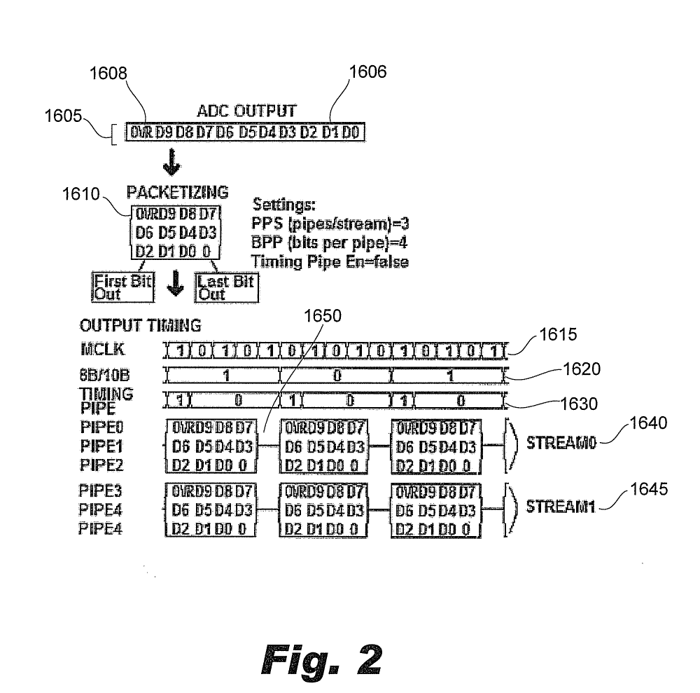

FIG. 2 shows one exemplary embodiment of the conversion of an analog-to-digital output into a balanced serial stream. The analog-to-digital output (1605) is first converted into packetized data (1610) by the serializer (1510; FIG. 1). According to the illustrative example given in FIG. 2, the analog-to-digital output (1605) consists of 10 data bits (1606) and an overflow bit (1608). The serializer (1510; FIG. 1) converts the parallel analog-to-digital output (1605) into a packet of data (1610) contains 12 bits. According to one exemplary embodiment, each row of the 12 bit packet (1610) is transmitted over an individual signal path or pipe (a path typically being a single ended signal or a differential pair). Thus, to transmit the packetized data (1610) three data pipes can be used, one for each row in the packet. In this example, for each packet, a data pipe transmits four bits of data each time the ADC outputs a data word. For example, the data pipe that transmits the bottom row of the packetized data (1610) must transmit the data bits [D2, D1, D0, 0]. The bit “D2” is the first bit out of the signal pipe and “0” is the last bit out of the signal pipe.

The packetized data is further encoded to have an equal number of “1”s and “0”s. This encoding necessitates adding extra bit times (1650). The final content shown the output streams (1640, 1650) will actually be the encoded data and therefore won't be in the same format shown in the figure for illustrative purposes. One common encoding scheme for balancing “1”s and “0”s is 8 B/10 B encoding, which requires 10 bit times to transmit 8 bits of raw input data.

In order to decode the serialized output, a number of timing signals can be generated and transmitted along with the packetized data stream. These timing signals (1615, 1620, 1630) are transmitted on individual signal pipes. The master clock signal (1615) toggles between a digital “1” and a digital “0” to time individual bits. The 8 B/10 B timing signal (1620) toggles each time an encoding packet starts or ends. The timing pipe (1630) toggles high at the beginning of each packet inside the stream. Together, these timing signals (1615, 1620, 1630) allow downstream devices to understand and decode the serialized data streams (1640, 1645). Although only two packetized data streams (1640, 1645) are shown in conjunction with the timing signals, any number of packetized data streams may be associated with the timing signals and without increasing the timing stream (1615, 1620, 1630) overhead requirement.

The packetized data streams (1640, 1645) each are comprised of three pipes which transmit each row of data within the packet. Stream 0 (1640) represents the packetized data from one analog-to-digital output (1605). Stream 1 (1645) contains the analog-to-digital output of a similar analog-to-digital converter (not shown). Each of the analog-to-digital converters requires 11 parallel output lines, resulting in a total of 22 output lines feeding into the serializer. As can be seen in FIG. 2, the serialized output including the overhead timing signals requires only nine output signal pipes.

The preceding description has been presented only to illustrate and describe embodiments and examples of the principles described. This description is not intended to be exhaustive or to limit these principles to any precise form disclosed. Many modifications and variations are possible in light of the above teaching.

What is claimed is:

1. A method of serializing parallel output from an analog-to-digital converter comprising:
receiving a parallel output from an analog-to-digital converter;
serializing said parallel output; and
encoding said serialized output such that a data stream carrying said serialized output is DC balanced.

2. The method of claim 1, further comprising isolating said digital-to-analog converter from low-frequency or DC voltages.

3. The method of claim 2, wherein said isolation is accomplished by interposing a capacitor in an output line carrying a portion of said data stream.

4. The method of claim 3, wherein said encoding said serialized output further comprises encoding said serialized output using an 8 B/10 B protocol.

5. The method of claim 2, further comprising transmitting framing or timing information in at least one separate data pipe.

6. The method of claim 5, wherein a plurality of serialized data streams utilizes the same framing or timing information.

7. The method of claim 6, wherein said framing or timing information comprises a master clock signal, an 8 B/10 B timing signal, and a framing signal.

8. The method of claim 1, wherein said serialized output is DC balanced by encoding said data stream with a substantially similar number of digital ones and zeros.

9. A system for serializing and DC balancing an analog-to-digital converter output comprising:
an analog-to-digital converter, said analog-to-digital converter receiving an analog signal and outputting corresponding digital data on a parallel bus, wherein said analog-to-digital converter is at least partially isolated from low-frequency or DC voltages on an output line;
a serializer configured to receive said digital data from said parallel bus, said serializer serializing said digital data into serial output;
a means for encoding said serial output such that said serial output is DC balanced.

10. The system of claim 9, wherein said analog-to-digital converter is at least partially isolated from low-frequency or DC voltages on said output line by placing a capacitance in said output line.

11. The system of claim 9, wherein said means for encoding comprises a separate chip, said separate chip receiving said serial output; said separate chip encoding said serial output such that said serial output is DC balanced.

12. The system of claim 9, wherein said means for encoding comprises circuitry internal to said serializer.

13. The system of claim 9, wherein said means for encoding comprises an 8 B/10 B encoder.

14. The system of claim 9, wherein said serial output further comprises a separate data stream containing timing or framing information.

15. The system of claim 9, wherein said serialized output is transmitted over low voltage differential pairs.

16. The system of claim 9, wherein said analog-to-digital converter, said serializer, and said encoder are contained within a load board, typical of those found in Automated Test Equipment (ATE) applications.

17. The system of claim 9, wherein said means for encoding is further configured to create a DC balanced output on each signal path that carries a portion of said serial output.

18. The system of claim 9, wherein said analog-to-digital converter, said serializer, and said encoder are contained within a single integrated circuit.
